(19) United States
(12) Patent Application Publication
(10) Pub. No.: US 2016/0228974 A1
(43) Pub. Date: Aug. 11, 2016

(54) ELECTRIC RESISTANCE WELDING METHOD AND USE THEREOF, AND ELECTRODE WELDING HEAD USED

(71) Applicant: Ching Wung LAM, Hong Kong (CN)

(72) Inventor: ChingWung LAM, Kwai Chung (HK)

(21) Appl. No.: 14/910,703

(22) PCT Filed: Jun. 19, 2014
(86) PCT No.: PCT/CN2014/080267

§ 371 Date: Feb. 8, 2016

(30) Foreign Application Priority Data
Jul. 3, 2013 (CN) 201310276322.4

(51) Int. Cl. B23K 11/30; H01M 2/26; H05K 3/32; B23K 11/20

(52) U.S. Cl. CPC B23K 11/30; B23K 11/20; H01M 2/26; H05K 3/328

(57) ABSTRACT

A resistance welding method comprises firstly lapping weldments in an up-down crossing manner or an overlapping manner, and then prepressing two electrodes in the same direction onto a top-layer weldment to form a current loop. A pressurization sheet made of a high resistance high-temperature resistant material which is parallel to the electrodes and is capable of moving upward and downward and applying a pressure to the welding position is arranged on the same side of the electrodes and between the two electrodes. The welding comprises the following steps: switching on a power supply of a welding machine, generating, by the current, resistance heat in the top-layer weldment to heat the top-layer weldment to a melting or plastic state; applying, by the pressurization sheet, a pressure to the top-layer weldment; cooling to crystallization; releasing the pressure applied by the pressurization sheet and the two electrodes and taking out the weldment.

### TECHNICAL FIELD

The present invention relates to a resistance welding method and a welding head used therein, and more particularly relates to a resistance welding method and an electrode welding head therefor with two electrodes parallelly arranged in the same direction.

### BACKGROUND

Resistance welding is a method for forming a metal combination by applying pressures to different weldments by means of the two electrodes and by using heating the weldments to a melting or plastic using the resistance heat effect generated when the current flows through the contact surface between the weldments and the surrounding region, upon combining workpieces.

Two commonly used resistance welding methods are spot welding and seam welding.

Spot Welding

As illustrated in FIG. 1, spot welding is a resistance welding method which assembles the weldments into a lap joint and tightly presses the same between two columnar electrodes 1, and then causes the base metal to melt by using the resistance heat to form a welding point 51. The spot welding is mainly used for welding thin plates.

Seam Welding

As illustrated in FIG. 2, the process of seam welding is similar to the spot welding. The difference lies only in that a disc-shaped roller electrodes 1 are in replace of the columnar electrodes 1, and the weldments are assembled into a lap or coupling joint and arranged between the two disc-shaped roller electrodes 1; and then the roller applies a pressure to the weldments to rotates, and power is continuously or intermittently fed, thereby achieving contiguous seal welding.

The seal welding is mainly used in the scenarios where the welding seams are regular and a sealed structure is required, with a plate thickness of generally less than 3 mm.

Balance Gap Resistance Welding

As illustrated in FIG. 3, in recent years, balance gap resistance welding is prevailing. As a type of spot welding, two parallelly and spacedly arranged electrodes 1 weld a top-layer weldment 3 and a bottom-layer weldment 4 whose resistance value is far less than that of a top-layer weldment 3 that are arranged in an up-down overlapping manner in the weldments. During welding, the two electrodes apply a pressure to the surface of the top-layer weldment 3 in the same direction; after a welding machine is supplied with power, the welding current flows from a high-level electrode 1, through the bottom-layer weldment 4, the top-layer wedlment 3, and to a low-level electrode 1 to finally form a current loop. As such, under the effect of the resistance heat, a welding point 51 is formed at the pressure-bearing joint between the top-layer weldment 3 and the bottom-layer weldment 4.

The balance gap resistance welding still has some defects in application:

1) Specific requirements are imposed to the resistance values of the top-layer weldment 3 and the bottom-layer weldment 4, that is, the resistance value of the bottom-layer weldment 4 needs to be far less than the resistance value of the top-layer weldment 3. In this way, the application scope of the welding method is subjected to some limitations.

2) When the resistance value of the top-layer weldment 3 is far less than the resistance value of the bottom-layer weldment 4, the welding current is short-circuited by the top-layer weldment 3, and thus the current does not flow through the bottom-layer weldment 4. Therefore, the top-layer weldment 3 may not be welded to the bottom-layer weldment 4. In addition, the welding current flows through the top-layer weldment 3, and under the effect of the resistance heat, is apt to fuse the top-layer weldment 3 between the two electrodes 1.

3) In the cross arrangement of the top-layer weldment 3 and the bottom-layer weldment 4, the balance gap resistance welding fails to work. This is because when the two electrodes 1 apply a pressure to the top-layer weldment 3, the bottom-layer weldment 4 below the top-layer weldment 3 and between the two electrodes 1 fails to cause the welding current to form a current loop. Therefore, no welding point 51 is formed between the top-layer weldment 3 and the bottom-layer weldment 4. In addition, in this state, since the two electrodes 1 apply a pressure to the top-layer weldment 3 in the same direction, it is likely that the top-layer weldment 3 between the two electrodes partially upwardly arches and thus fails to be in close contact with the bottom-layer weldment 3.

4) The welding method fails to be applied to the manufacture and welding process of a non-contact or double-interface IC card 6, or fails to be applied to the welding process of the electrodes 1 of the battery 7 in the battery management system to the external lead thereof.

In the related art, the welding method for welding the non-contact or double-interface IC card 6 to the electrodes 1 of the battery 7 and the external lead thereof is as follows:

A. With respect to the non-contact or double-interface IC card 6, during welding of the chip thereof and the induction coil lead 62, another welding method is generally used, for example, hot welding, ultrasonic welding or laser welding is used to firstly weld the induction coil lead 62 to a transitional metal foil, and then weld the transitional metal foil to the IC chip copper foil 61 via the connecting lead 63. All these welding methods may have the following defects. Firstly, over-high temperatures during the welding cause partial deformation to the plastic sheet of the IC card 6, thereby affecting the appearance and quality or causing damage to the IC chip. Secondly, the connecting lead is not directly welded, but a transitional metal foil is needed as a connecting medium, thereby greatly increasing the material cost. Thirdly, the welding operator needs to be highly skilled; otherwise, many quality issues may be caused. Fourthly, the welding machine is expensive, and thus the welding cost is high.

B. The battery 7 in the battery set of the battery management system is welded to the external lead generally by using another welding method. To be specific, firstly a nickel sheet whose resistance value is higher than that of a copper material is welded to the electrodes of the battery 7, and then the external lead is welded to the nickel sheet. This welding method, however, has the following disadvantages. Firstly, an intermediate transitional welding sheet—the nickel sheet or another metal sheet is needed, thereby increasing the material cost. Secondly, since the conductivity of nickel is poorer than that of copper, the welding structure greatly lowers the output current of the battery set.

### SUMMARY

A technical problem to be solved by the present invention is to provide a resistance welding method. In this method, two electrodes of a welding machine apply a pressure to crossed or overlapped top-layer weldments in the same direction and supply power thereto, which causes the top-layer weldments between the two electrodes to be in a melting or plastic state. As such, the top-layer weldment and the bottom-layer weldments are welded together under a pressure applied by a pressurization sheet.

To solve the above technical problem, the present invention employs the following technical solution:

The present invention provides a resistance welding method, comprising firstly lapping weldments in an up-down crossing manner or an overlapping manner, and then prepressing two electrodes in the same direction onto a top-layer weldment to form a current loop; wherein the two electrodes are parallelly arranged on two sides of a welding position formed by contact of the top-layer weldment and a bottom-layer weldment, and a pressurization sheet made of a high resistance high-temperature resistant material which is parallel to the electrodes and is capable of moving upward and downward and applying a pressure to the welding position is arranged on the same side of the electrodes and between the two electrodes, and the welding comprises the following steps:

1) switching on a power supply of a welding machine, and adjusting a conduction current to a corresponding predetermined value according to material characteristics of the top-layer weldment, and causing the conduction current to flow from one electrode through the top-layer weldment to the other electrode to form a loop;

2) generating, by the current flowing between the two electrodes, resistance heat in the top-layer weldment in this section, wherein when current conduction time reaches a predetermined time, the top-layer weldment in this section is heated to a melting or plastic state;

3) contacting, by the pressurization sheet by means of moving upward and downward, the top-layer weldment at the welding position;

4) causing the pressurization sheet to apply a constant pressure to the top-layer weldment in the melting or plastic state, such that the top-layer weldment at the welding position is in close contact with the bottom-layer weldment; and disconnecting the current loop between the two electrodes, such that atoms in the top-layer weldment in the melting or plastic state are spread towards the interior of metal grains of the bottom-layer weldment under the pressure applied by the pressurization sheet, and a welding point is formed at the welding position upon cooling and crystallization; and

5) releasing the pressure applied by the pressurization sheet and the two electrodes to the top-layer weldment, upwardly moving the pressurization sheet to return to the original position, and taking out the weldment.

The top-layer weldment and the bottom-layer weldment are metal yarns, metal wires, metal sheets, or metal plates.

The top-layer weldment is at least one metal yarn, metal wire, or metal rod.

The pressurization sheet is made of a ceramic material, a silica material, or a bakelite material.

The two electrodes are parallelly arranged and have the same length.

The present invention further provides a welding method for welding an IC card chip and a connecting lead thereof, comprising welding one end of a connecting lead to an IC chip copper foil, and welding the other end of the connecting lead to the an IC induction coil lead; wherein the welding method comprises the following steps:

1) lapping one end of the connecting lead and the IC chip copper foil;

2) welding by using the resistance welding method according to claim 1, that is, pressing lower ends of two electrodes onto the connecting lead, an intersection between the connecting lead and the IC chip copper foil being located between the two electrodes;

3) switching on a power supply of a welding machine, such that the temperature of the connecting lead at the intersection rises under the effect of resistance heat, which causes the connecting lead to change from a solid state to a melting or plastic state;

4) then causing a pressurization sheet between the two electrodes to apply from top to bottom a constant pressure to the connecting lead at the intersection, such that the connecting lead at the intersection is in close contact with the IC chip copper foil, and meanwhile disconnecting a current loop between the two electrodes, such that the connecting lead in the melting or plastic state cools to crystallization under the pressure applied by the pressurization sheet, and then is welded to the IC chip copper foil;

5) releasing the pressure applied by the pressurization sheet and the two electrodes to the connecting lead, upwardly moving the pressurization sheet to return to the original position;

6) according to the above method, welding the other end of the connecting lead to the IC induction coil lead.

The present invention further provides a welding method for welding battery electrodes in a battery set to an external lead, comprising the following steps:

1) lapping a copper sheet or copper wire on electrodes of a battery for welding;

2) welding by using the resistance welding method according to the present invention, that is, pressing lower ends of the two electrodes onto the copper sheet or copper wire, wherein a welding position of the copper sheet or copper wire with the electrodes of the battery is between the two electrodes;

3) switching on the power supply of the welding machine, such that the temperature of the copper sheet or copper wire at the welding position rises under the effect of resistance heat, which causes the copper sheet or copper wire to change from a solid state to a melting or plastic state;

4) then causing a pressurization sheet between the two electrodes to apply from top to bottom a constant pressure to the copper sheet or copper wire at the welding position, such that the copper sheet or copper wire at the welding position is in close contact with the battery, and meanwhile disconnecting a current loop between the two electrodes, such that the copper sheet or copper wire in the melting or plastic state cools to crystallization under the pressure applied by the pressurization sheet, and then is welded to the battery;

5) releasing the pressure applied by the pressurization sheet and the two electrodes to the copper sheet or copper wire, upwardly moving the pressurization sheet to return to the original position;

6) according to the above method, welding electrodes of other batteries in the battery set to the external lead or conducting sheet.

The present invention further provides an electrode welding head used in the method, wherein the electrode welding head is formed by a left electrode and a right electrode that are parallelly arranged, and a pressurization sheet sandwiched between the left electrode and the right electrode, the left electrode and the right electrode being bar rods, the two electrodes having a circular, semi-circular, rectangular or trapezoid cross section, the pressurization sheet being made of a high resistance high-temperature resistance material and capable of moving upward and downward between the two electrodes.

The left electrode and the right electrode are parallelly arranged, upper cross sections of the two electrodes are both in a circle shape, and opposing surfaces are planar surfaces, identical rectangular grooves being arranged on the two planar surfaces, the rectangular grooves extending from top to bottom to lower portions of the electrodes; lower cross sections of the two electrodes gradually narrowing, lower end surfaces are both in a rectangular shape, and longitudinal sections of portions proximate to the lower end surfaces on the two electrodes are in an inverted trapezoid shape; the pressurization sheet is a ceramic sheet in a rectangular block shape, which is arranged the rectangular grooves of the two electrodes, isolates the left electrode and the right electrode and is capable of moving upward and downward therein, wherein a longitudinal section of a lower portion proximate to the lower end surface of the pressurization sheet is in an inverted trapezoid shape.

The left electrode and the right electrode have the same length.

As compared with the prior art, the present invention employs electrodes of the welding machine that are parallelly arranged in the same direction, and a pressurization sheet arranged between two electrodes. With such a structure, during welding of the weldments that are arranged in a lapping or overlapping manner by using the resistance heat, the weldments may be welded together with the assistance of the pressurization sheet only when the two electrodes apply a pressure to the weldment arranged at the top in the same direction. With the method according to the present invention, any metal yarns and wires, wires and wires, wire and sheets or sheets and sheets may be welded. In particular, an IC card chip may be directly welded to an IC induction coil and battery electrodes in a battery set may be directly welded to a copper sheet or copper wire, thereby achieving a better welding effect. To be specific, the IC card obtained upon welding by using the method according to the present invention is flat without any deformation, and wires and wires are directly welded. This saves the transitional metal sheet used in welding in the related art. Further, in the resulted battery set, the copper sheet or copper wire replace the original nickel sheet to directly connect to the electrodes of the battery. As such, the output current of the battery set is greatly improved.

The electrode welding head according to the present invention employs parallelly arranged electrodes and a pressurization sheet which is arranged between the two electrodes and capable of moving upward and downward and applying a pressure to the weldment. With such design, the resistance welding method according to the present invention may be practiced by unidirectionally applying a pressure and supplying power to the same weldment and hence carrying out resistance welding to the weldment.

### BRIEF DESCRIPTION OF THE DRAWINGS

The present invention is further described with reference to and the attached drawings and specific embodiments.

FIG. 1 is a schematic view of spot welding in resistance welding in the related art;

FIG. 2 is a schematic view of seam welding in resistance welding in the related art;

FIG. 3 is a schematic view of balance gap resistance welding in the related art;

FIG. 4 is a schematic state view of an electrode and a welding position in a resistance welding method according to the present invention;

FIG. 5 is a schematic welding state view of an IC card chip and a connecting lead according to the present invention;

FIG. 6 is a schematic welding state of a battery electrode in a battery set and an external lead according to the present invention; and

FIG. 7 is a schematic structural view of an electrode welding head used in the resistance welding method according to the present invention.

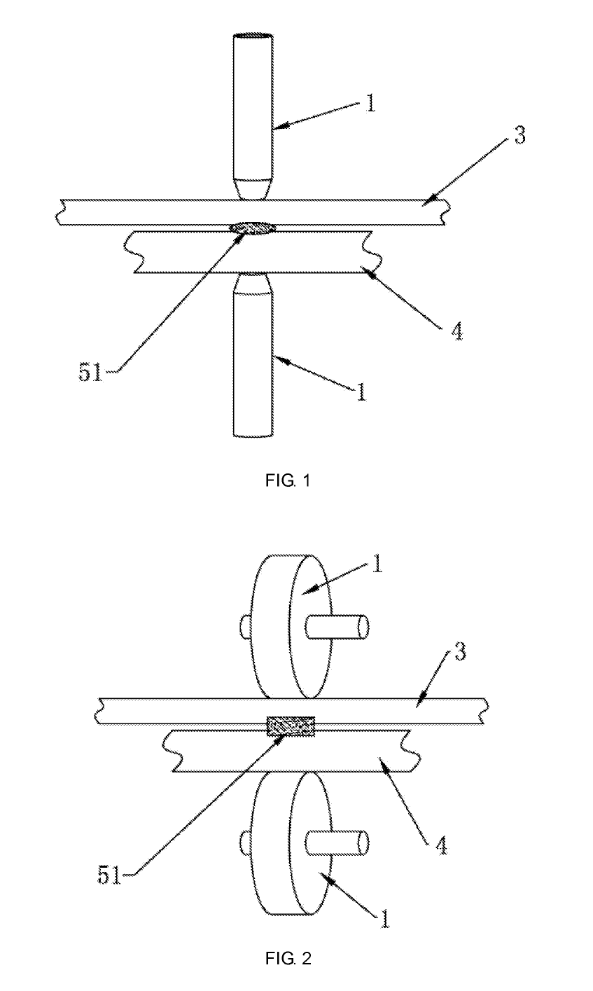

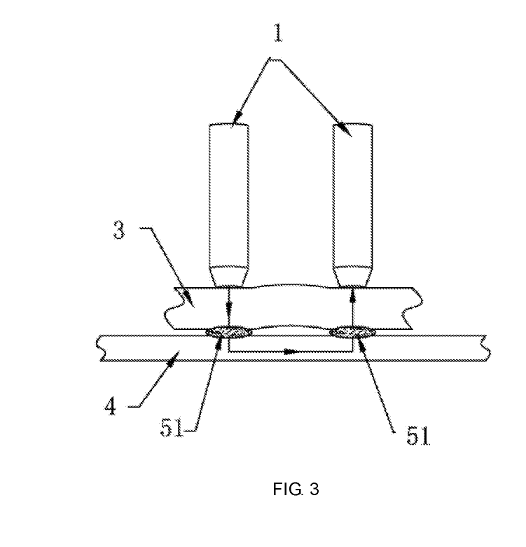

Reference numerals and denotations thereof:

1—electrode, 11—left electrode, 12—right electrode, 13—rectangular groove, 2—pressurization sheet 2, 3—top-layer weldment, 4—bottom-layer weldment, 5—welding position, 51—welding point, 6—IC card, 61—IC chip copper foil, 62—IC induction coil lead, 63—connecting lead, 7—battery, 71—copper sheet or copper wire.

### DETAILED DESCRIPTION

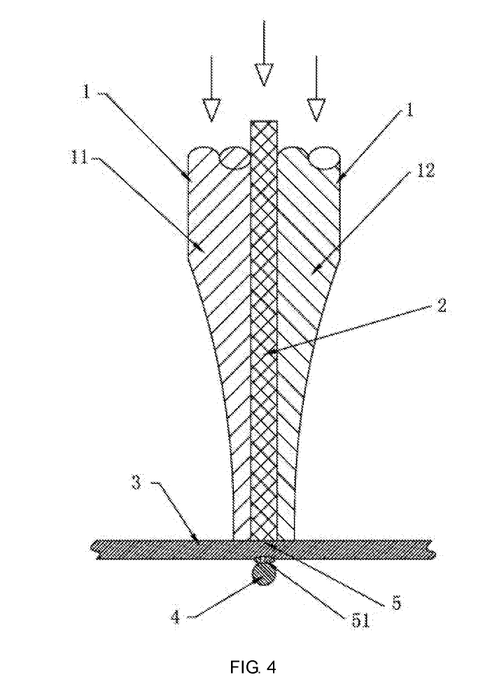

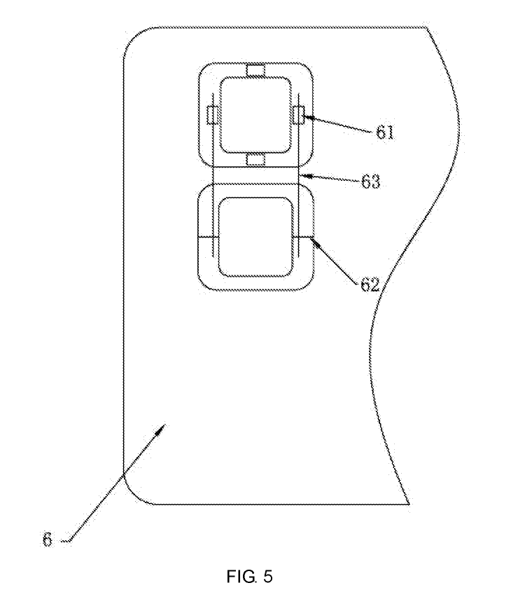

As illustrated in FIG. 4, the present invention provides a resistance welding method. The welding method is particularly applicable to welding of any metal yarns and wires, wires and wires, wire and sheets or sheets and sheets in the field of microelectronics, more particularly lapping (that is, a crossing angle between the weldments may be an acute angle, a right angle or up-down overlapping, wherein the weldment over the lapping contact point is referred to as a top-layer weldment 3, the weldment below the lapping contact point is referred to as a bottom-layer weldment 4, and both the top-layer weldment 3 and the bottom-layer weldment 4 may be a single one or multiple) of weldments (the weldments may be metal yarns, wires, rods, sheets or plates) in an up-down crossing or overlapping manner. Afterwards, two electrodes 1 are prepressed onto the weldments to form a current loop. The two electrodes 1 according to the present invention are parallelly arranged in the same direction on two sides of a welding position 5 formed by contact of the top-layer weldment 3 and the bottom-layer weldment 4 (generally the two electrodes 1 are parallelly arranged in the same direction, or the arrangement of the electrodes may be adjusted according to the actual conditions upon lapping of the weldments, that is, the two electrodes 1 may be oppositely or reversely inclined, with an inclination angle of ±3°). In addition, the two electrodes 1 are prepressed onto the same weldment whose contact point is located on the top-layer weldment 3, and the electrodes 1 and the top-layer weldment 3 are in a positive conduction connection state. A pressurization sheet 2 which is made of a high resistance (the term “high resistance” means that the resistance value of the pressurization sheet 2 is greater than the resistance value of the top-layer weldment 3, that is, during welding, the welding current flows from a high-level electrode 1 through the top-layer weldment 3 and then flows back from a low-level electrode 1, but fails to flow back upon short circuit by the pressurization sheet 2) high-temperature resistance material, parallel to the two electrodes 1 and capable of moving upward and downward between the two electrodes is arranged on the same side of the electrodes 1 and between the two electrodes 1. During welding, the pressurization sheet 2 moves downward to contact the welding position 5 and applies a constant pressure to the top-layer weldment 3, that is, under the pressure applied by the pressurization sheet 2, the top-layer weldment 3 at the welding position 5 is in close contact with the bottom-layer weldment 4. The pressurization sheet 2 may be made of a ceramic material or a silica material or a bakelite material which is resistant to high temperatures.

The welding employs the following steps:

1) switching on a power supply of a welding machine, and adjusting a conduction current to a corresponding predetermined value according to material characteristics of the top-layer weldment 3, and causing the conduction current to flow from one electrode 1 through the top-layer weldment 3 to the other electrode 1 to form a loop;

3) generating, by the current flowing between the two electrodes 1, resistance heat in the top-layer weldment 3 in this section, wherein when current conduction time reaches a predetermined time, the top-layer weldment 3 in this section is heated to a melting or plastic state; to be specific, the atoms in the top-layer weldment 3 which is heated to the melting or plastic state are capable of spreading around; since the electrodes 1 are only in contact with the top-layer weldment 3, the conduction current does not flow through the bottom-layer weldment 4, and the atom vacancy motion is unidirectional, that is, resistance heat is not generated in the bottom-layer weldment 4, and thus the weldment is not likely in the melting or plastic state; as such, electric energy is saved, and in addition integrity of the member (when the member is made of a thermally deformable material) bearing the bottom-layer weldment 4 is ensured upon high temperature welding;

3) when the top-layer weldment 3 is in the melting or plastic state, contacting, by the pressurization sheet 2 by means of moving upward and downward, the top-layer weldment 3 at the welding position 5 (the pressurization sheet 2 may also apply a constant pressure to the top-layer weldment at the welding position 5 while the two electrodes 1 apply a pressure to the top-layer weldment 3);

4) causing the pressurization sheet 2 to apply a constant pressure to the top-layer weldment 3 in the melting or plastic state (the pressure is specifically defined according to the material characteristics of the weldment), such that the top-layer weldment 3 at the welding position 5 is in close contact with the bottom-layer weldment 4; disconnecting the current loop between the two electrodes 1, such that atoms in the top-layer weldment 3 in the melting or plastic state are spread towards the interior of metal grains of the bottom-layer weldment 4 under the pressure applied by the pressurization sheet 2, and a solid solution is formed in the metal at the border between the top-layer weldment 3 and the bottom-layer weldment 4 and proximate the bottom-layer weldment 4, that is, causing the top-layer weldment 3 in the melting or plastic state to cool to crystallization under the pressure applied by the pressurization sheet 2; and finally forming a vertical grain boundary constituted by a dislocation wall and by mixture of atoms of at least two metals, such that the weldments having the same or different metal materials are welded together; and

5) after the top-layer weldment 4 are the bottom-layer weldment are welded together, releasing the pressure applied by the pressurization sheet 2 and the two electrodes 1 to the top-layer weldment 3, upwardly moving the pressurization sheet 2 to return to the original position, and taking out the weldment.

As illustrated in FIG. 5, the present invention further provides a welding method for welding the chip of an IC card 6 to a connecting lead 63 thereof, which is applicable to welding of the chip of a non-contact and double-interface IC card 6 to the connecting lead 63 thereof.

By using the resistance welding method according to the present invention, one end of the connecting lead 63 is firstly welded to the IC chip copper foil 61, and then the other end of the connecting lead 63 is welded to the IC induction coil lead 62. The welding method comprises the following steps:

1) lapping one end of the connecting lead 63 on the IC chip copper foil 61;

2) welding by using the resistance welding method according to the present invention, that is, pressing lower ends of the two electrodes 1 onto the connecting lead 63;

3) switching on the power supply of the welding machine, such that the temperature of the connecting lead 63 between the two electrodes 1 rises under the effect of resistance heat, which causes the connecting lead 63 to change from a solid state to a melting or plastic state;

4) then causing a pressurization sheet 2 (or the pressurization sheet 2 may be pressed on the connecting lead 63 in advance) between the two electrodes 1 to apply from top to bottom a constant pressure to the connecting lead 63 in the melting or plastic state, such that the connecting lead 63 is in close contact with the IC chip copper foil 61; and meanwhile disconnecting a current loop between the two electrodes 1, such that under the pressure applied by the pressurization sheet 2, the atoms in the connecting lead 63 in the melting or plastic state are spread towards the interior of the metal grains of the IC chip copper foil 61 and thus a solid solution is formed on a surface layer of the IC chip copper foil 61 at the border between the connecting lead 63 and the IC chip copper foil 61, that is, causing the connecting lead 63 in the melting or plastic state to cool to crystallization under the pressure applied by the pressurization sheet; as such the connecting lead 63 and the IC chip copper foil 61 are welded;

5) releasing the pressure applied by the pressurization sheet 2 and the two electrodes 1 to the connecting lead 63, upwardly moving the pressurization sheet 2 to return to the original position;

6) according to the above method, lapping and welding the other end of the connecting lead 63 to the IC induction coil lead 62 in a wire-wire crossing manner, which saves the introduction of a transitional metal sheet during the welding of the chip of the IC card 6 to the connecting lead in the related art.

The present invention is characterized by thoroughly revolutionizing the wire connection method on the traditional IC card 6, particularly providing a simple, effective but economic welding solution for manufacture of double-interface cards (combi-cards) (the welding method in the related art is to weld the IC induction coil lead 62 to a metal foil by means of hot welding, and then connecting the metal foil to the IC chip via the connecting lead 63 by means of ultrasonic welding, laser welding or heat welding; this method is complicate and poor in reliability, and in additional the heat generated during the welding may cause the plastic sheet of the IC card 6 to deform, thereby affecting the appearance and quality).

To enable quicker and more convenient welding using the method according to the present invention, during winding of the induction coil, one to two weld wire segments with a “−” shape or “Z” shape wire tail may be reserved at the head and tail of the coil. The induction coil is directly connected to the IC chip via the connecting lead 63 by using the welding method according to the present invention.

The welding method according to the present invention may also be combined with the related art, and using the method, the chip of the IC card 6 is welded to the induction coil thereof as follows:

A metal foil is prepared; the induction coil lead 62 is welded on the metal foil in advance by means of hot pressure welding, and then the IC chip copper foil 61 is welded to the metal foil via the connecting lead 63 by using the method according to the present invention. As such, the manufacture processes are greatly simplified, and the connection quality and reliability are improved. In addition, the heat generated by the welding is highly concentrated, which may not affect the plastic body at the bottom and surroundings, or may not cause the metal layer on the front surface of the IC chip to be subjected to decoloration and oxidation. Therefore, the IC card 6 having good appearance quality is obtained.

With the welding method for welding the chip of the IC card 6 to the connecting lead 63 thereof according to the present invention, the chip of the IC card 6 is welded to the induction coil thereof in a manner of crossing micro leads. In this way, the two crossed fine leads deployed on a common plastic bottom plate may be subjected to resistance spreading welding. In addition, the heat generated during the welding may not cause deformation and damage to the plastic bottom plate, and this design is pioneering in this field.

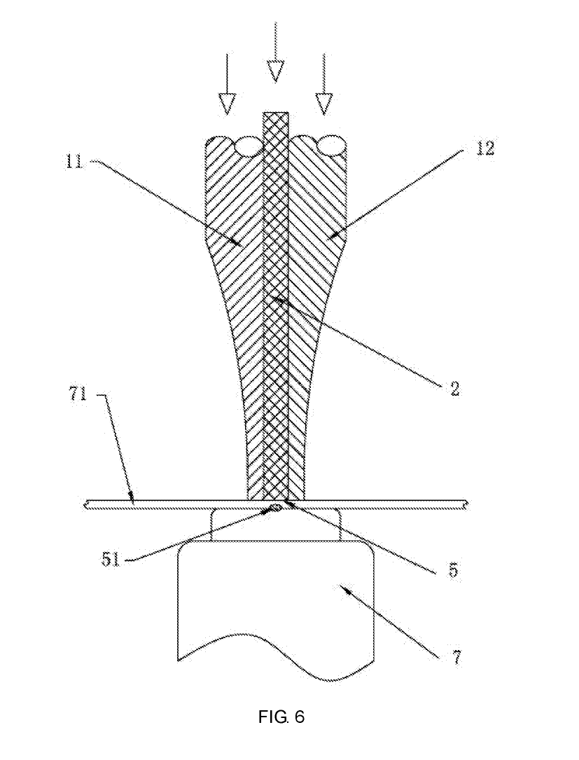

As illustrated in FIG. 6, the welding method for welding the electrodes of the battery 7 in the battery set to the external lead according to the present invention is applicable to welding of the electrodes of the battery 7 in the batter set of a battery management system and the external lead thereof, and the welding method comprises the following steps:

1) firstly lapping a copper sheet or copper wire 71 onto the electrodes (that is, the positive pole and the negative pole) of a battery 7 for welding;

2) welding by using the resistance welding method according to the present invention, that is, pressing lower ends of the two electrodes 1 onto the copper sheet or copper wire 71, wherein a welding position 5 of the copper sheet or copper wire 71 with the electrodes of the battery 7 is between the two electrodes 1;

3) switching on the power supply of the welding machine, such that the temperature of the copper sheet or copper wire 71 at the welding position 5 rises under the effect of resistance heat, which causes the copper sheet or copper wire 71 to change from a solid state to a melting or plastic state;

4) then causing a pressurization sheet 2 between the two electrodes 1 to apply from top to bottom a constant pressure to the copper sheet or copper wire 71 at the welding position 5, such that the copper sheet or copper wire 71 at the welding position 5 is in close contact with the battery 7, and meanwhile disconnecting a current loop between the two electrodes 1, such that the copper sheet or copper wire 71 in the melting or plastic state cools to crystallization under the pressure applied by the pressurization sheet 2, and then is welded to the battery 7;

5) releasing the pressure applied by the pressurization sheet 2 and the two electrodes 1 to the copper sheet or copper wire 71, upwardly moving the pressurization sheet 2 to return to the original position; and

6) according to the above method, welding electrodes of the other batteries 7 in the battery set.

When the method according to the present invention is applied to welding of the battery 7 of a battery set to the external lead thereof, the output current of the battery set may be greatly improved.

In the related art, firstly a nickel sheet whose conductive property is poorer than the copper material is welded, as a transitional member, to the electrodes of the battery 7, and then the copper sheet or copper wire 71 is welded to the nickel sheet. This connection manner causes limitations to the output current of the battery set.

With the method according to the present invention, a metal material, particularly the copper sheet or copper wire 71 having good conductive property is directly welded to the electrodes of the battery 7, which causes no damage to the battery 7 or causes no adverse impact to the performance of the battery 7. This design is also pioneering in this field, and would be a magnificent breakthrough particularly in the application of the high power battery 7.

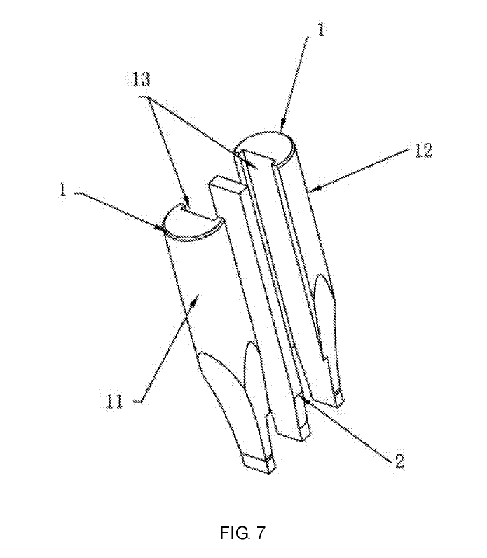

As illustrated in FIG. 7, a welding head used in various methods according to the present invention is formed by a left electrode 11 and a right electrode 12 that are parallelly arranged, and a pressurization sheet 2 sandwiched between the left electrode 11 and the right electrode 12. The left electrode 11 and the right electrode 12 are bar rods, the two electrodes 1 have a circular, semi-circular, rectangular or trapezoid upper cross section with the lower cross section gradually narrowing, and the lower end surfaces are both in a rectangular shape. The pressurization sheet 2 is made of a high resistance high-temperature resistance material and capable of moving upward and downward between the two electrodes 1, and the lower end surface is in a rectangular shape.

The lengths of the two electrodes 1 may be defined according to the actual lapping of the weldments, which may be defined as the same or different.

The left electrode 11 and the right electrode 12 are symmetric, or may be asymmetric according to the actual lapping of the weldments. Generally the left electrode 11 and the right electrode 12 are made of a specially resistance welded copper alloy, or may be made of another metal or alloy due to the requirements on the conductive property and wear-resistance. The appearance of the electrode is generally a cylinder, or may be adaptively adjusted according to actual lapping and shape of the weldments. The thickness and the end face shape of the pressurization sheet 2 may also be adaptively adjusted according to actual lapping and shape of the weldments.

The welding head of the electrodes 1 according to the present invention preferably has the following structure:

The left electrode 11 and the right electrode 12 are parallelly arranged. Upper ends of the electrodes 11 may be inserted into and fixed to the corresponding insertion holes on the welding machine. The pressurization sheet 2 made of a conductive ceramic material is sandwiched between the two electrodes 1, and isolates and insulates the two electrodes 1. When the two electrodes and the pressurization sheet are combined, they are wedge-shaped, larger at the top and smaller at the bottom. The left electrode 11 and the right electrode 12 have the same structure and length, with the upper cross sections being both a semi-circular shape, and the circular arc facing outward. The surface by which the cross section is in contact with the pressurization sheet 2 is planar, referred to as a planar section. An inwardly concave rectangular groove 13 is arranged on both of the upper half portions of the two planar sections. The rectangular groove 13 extends from top to bottom to the intermediate lower portions of the electrodes 1. At the lower half portions of the planar sections, and at the portions proximate to the lower end surfaces, the outer circular arc surfaces of the two electrodes 1 gradually narrow, and form a shape with the cross section being an inverted trapezoid shape (that is, larger at the top and smaller at the bottom), and the lower end surface is in a rectangular shape. The pressurization sheet 2 is a rectangular block, and is arranged in the grooves of the two electrodes 1 and capable of moving upward and downward. The cross section of the pressurization sheet 2 mates with the cross section of a through hole formed after the rectangular grooves 13 on the two electrodes 1 are combined, wherein a longitudinal section of a lower portion proximate to the lower end surface of the pressurization sheet 2 is in an inverted trapezoid shape.

Detailed above is further description of the present disclosure with reference to some preferred embodiments, and is not intended to limit the scope of the present disclosure in terms of implementation. Persons of ordinary skill in the art would make several equivalent replacements or obvious variations without departing from the inventive concept of the present invention, with the same performance and usage. However, these replacements and variations shall all be considered as falling within the protection scope as defined by the appended claims.

1. A resistance welding method, comprising firstly lapping weldments in an up-down crossing manner or an overlapping manner, and then prepressing two electrodes in the same direction onto a top-layer weldment to form a current loop; wherein the two electrodes are parallelly arranged on two sides of a welding position formed by contact of the top-layer weldment and a bottom-layer weldment, and a pressurization sheet made of a high resistance high-temperature resistant material which is parallel to the electrodes and is capable of moving upward and downward and applying a pressure to the welding position is arranged on the same side of the electrodes and between the two electrodes, and the welding comprises the following steps:
1) switching on a power supply of a welding machine, and adjusting a conduction current to a corresponding predetermined value according to material characteristics of the top-layer weldment, and causing the conduction current to flow from one electrode through the top-layer weldment to the other electrode to form a loop;
2) generating, by the current flowing between the two electrodes, resistance heat in the top-layer weldment in this section, wherein when current conduction time reaches a predetermined time, the top-layer weldment in this section is heated to a melting or plastic state;
3) contacting, by the pressurization sheet by means of moving upward and downward, the top-layer weldment at the welding position;
4) causing the pressurization sheet to apply a constant pressure to the top-layer weldment in the melting or plastic state, such that the top-layer weldment at the welding position is in close contact with the bottom-layer weldment; and disconnecting the current loop between the two electrodes, such that atoms in the top-layer weldment in the melting or plastic state are spread towards the interior of metal grains of the bottom-layer weldment under the pressure applied by the pressurization sheet, and a welding point is formed at the welding position upon cooling and crystallization; and
5) releasing the pressure applied by the pressurization sheet and the two electrodes to the top-layer weldment, upwardly moving the pressurization sheet to return to the original position, and taking out the weldment.

2. The resistance welding method according to claim 1, wherein the top-layer weldment and the bottom-layer weldment are metal yarns, metal wires, metal sheets, or metal plates.

3. The resistance welding method according to claim 1, wherein the top-layer weldment is at least one metal yarn, metal wire, or metal rod.

4. The resistance welding method according to claim 1, wherein the pressurization sheet is made of a ceramic material, a silica material, or a bakelite material.

5. The resistance welding method according to claim 1, wherein the two electrodes are parallelly arranged and have the same length.

6. A welding method for welding an IC card chip to a connecting lead thereof, comprising welding one end of a connecting lead to an IC chip copper foil, and welding the other end of the connecting lead to the an IC induction coil lead; wherein the welding method comprises the following steps:
1) lapping one end of the connecting lead and the IC chip copper foil;
2) pressing lower ends of two electrodes onto the connecting lead, an intersection between the connecting lead and the IC chip copper foil being located between the two electrodes;
3) switching on a power supply of a welding machine, such that the temperature of the connecting lead at the intersection rises under the effect of resistance heat, which causes the connecting lead to change from a solid state to a melting or plastic state;
4) then causing a pressurization sheet between the two electrodes to apply from top to bottom a constant pressure to the connecting lead at the intersection, such that the connecting lead at the intersection is in close contact with the IC chip copper foil, and meanwhile disconnecting a current loop between the two electrodes, such that the connecting lead in the melting or plastic state cools to crystallization under the pressure applied by the pressurization sheet, and then is welded to the IC chip copper foil;
5) releasing the pressure applied by the pressurization sheet and the two electrodes to the connecting lead, upwardly moving the pressurization sheet to return to the original position; and
6) according to the above method, welding the other end of the connecting lead to the IC induction coil lead.

7. A welding method for welding battery electrodes in a battery set to an external lead, comprising:
1) lapping a copper sheet or copper wire on electrodes of a battery for welding;
2) pressing lower ends of the two electrodes onto the copper sheet or copper wire, wherein a welding position of the copper sheet or copper wire with the electrodes of the battery is between the two electrodes;
3) switching on a power supply of a welding machine, such that the temperature of the copper sheet or copper wire at the welding position rises under the effect of resistance heat, which causes the copper sheet or copper wire to change from a solid state to a melting or plastic state;
4) then causing a pressurization sheet between the two electrodes to apply from top to bottom a constant pressure to the copper sheet or copper wire at the welding position, such that the copper sheet or copper wire at the welding position is in close contact with the battery, and meanwhile disconnecting a current loop between the two electrodes, such that the copper sheet or copper wire in the melting or plastic state cools to crystallization under the pressure applied by the pressurization sheet, and then is welded to the battery;
5) releasing the pressure applied by the pressurization sheet and the two electrodes to the copper sheet or copper wire, upwardly moving the pressurization sheet to return to the original position; and
6) according to the above method, welding electrodes of other batteries in the battery set to the external lead or conducting sheet.

8. An electrode welding head comprising a left electrode and a right electrode that are parallelly arranged, and a pressurization sheet sandwiched between the left electrode and the right electrode, the left electrode and the right electrode being bar rods, the two electrodes having a circular, semi-circular, rectangular or trapezoid cross section, the pressurization sheet being made of a high resistance high-temperature resistance material and capable of moving upward and downward between the two electrodes.

9. The electrode welding head according to claim 8, wherein the left electrode and the right electrode are parallelly arranged, upper cross sections of the two electrodes are both in a circle shape, and opposing surfaces are planar surfaces, identical rectangular grooves being arranged on the two planar surfaces, the rectangular grooves extending from top to bottom to lower portions of the electrodes; lower cross sections of the two electrodes gradually narrowing, lower end surfaces are both in a rectangular shape, and longitudinal sections of portions proximate to the lower end surfaces on the two electrodes are in an inverted trapezoid shape; the pressurization sheet is a ceramic sheet in a rectangular block shape, which is arranged the rectangular grooves of the two electrodes, isolates the left electrode and the right electrode and is capable of moving upward and downward therein, wherein a longitudinal section of a lower portion proximate to the lower end surface of the pressurization sheet is in an inverted trapezoid shape.

10. The electrode welding head according to claim 8, wherein the left electrode and the right electrode have the same length.

11. The electrode welding head according to claim 9, wherein the left electrode and the right electrode have the same length.
